(19) United States
(12) Patent Application Publication
(10) Pub. No.: US 2026/0280546 A1
(43) Pub. Date: Sep. 17, 2026

(54) SWITCHING CIRCUIT AND POWER SUPPLY CIRCUIT

(71) Applicant: SHARP KABUSHIKI KAISHA, Sakai City (JP)

(72) Inventor: TAKESHI SHIOMI, Sakai City (JP)

(21) Appl. No.: 19/556,200

(22) Filed: Mar. 4, 2026

(30) Foreign Application Priority Data
Mar. 11, 2025 (JP) 2025-037995

(51) Int. Cl. H03K 17/06; H02M 1/088

(52) U.S. Cl. CPC H03K 17/063; H02M 1/088; H03K 2217/0063; H03K 2217/0072

(57) ABSTRACT

A switching circuit includes two series transistors: a high-withstand-voltage transistor and a low-withstand-voltage transistor. A high-voltage terminal of the low-withstand-voltage transistor is connected to a reference terminal of the high-withstand-voltage transistor. A control terminal of the high-withstand-voltage transistor includes a transistor-control path connected to a reference terminal of the low-withstand-voltage transistor. The transistor-control path includes parallel elements: a gate resistor and a gate diode. An inter-terminal capacitance of the gate diode is equal to or less than 20% of an input capacitance of the high-withstand-voltage transistor.

### CROSS-REFERENCE TO RELATED APPLICATION

The present application claims priority from Japanese Application JP2025-037995, filed on March 11, 2025, the content of which is hereby incorporated by reference into this application.

### BACKGROUND

### 1. Field

The following disclosure relates to a switching circuit and a power supply circuit.

### 2. Description of the Related Art

Japanese Unexamined Patent Application Publication No. 2016-220468 is disclosed as an example configuration of the switching circuit.

### SUMMARY

Such a switching circuit still has room for improvement.

The Specification discloses a stable switching circuit and a stable power supply circuit.

To solve the above problem, a switching circuit according to one aspect of the present disclosure is a switching circuit including two series transistors.

The switching circuit is structured such that a high-withstand-voltage transistor is disposed on a high-voltage side, and a low-withstand-voltage transistor is disposed on a low-voltage side, and such that a high-voltage terminal of the low-withstand-voltage transistor is connected to a reference terminal of the high-withstand-voltage transistor, and the switching circuit includes a transistor-series path from a reference terminal of the low-withstand-voltage transistor to the reference terminal of the high-withstand-voltage transistor.

A control terminal of the high-withstand-voltage transistor includes a transistor-control path connected to the reference terminal of the low-withstand-voltage transistor.

The transistor-control path includes a gate resistor.

The gate resistor is connected to a gate diode in parallel.

The gate diode is structured such that an anode is connected to the control terminal of the high-withstand-voltage transistor, such that a cathode is connected to the reference terminal of the low-withstand-voltage transistor, and such that an inter-terminal capacitance is equal to or less than 20% of an input capacitance of the high-withstand-voltage transistor.

To solve the above problem, a power supply circuit according to one aspect of the present disclosure includes the switching circuit.

According to the present disclosure, the switching circuit and the power supply circuit operate stably.

### BRIEF DESCRIPTION OF THE DRAWINGS

FIG. 1 illustrates a switching circuit of the present disclosure;

FIG. 2 illustrates the operation waveform of the switching circuit of the present disclosure; and

FIG. 3 illustrates a power supply circuit including the switching circuit of the present disclosure.

### DETAILED DESCRIPTION OF THE DISCLOSURE

### First Embodiment

The following lists abbreviations that will be used in the Specification: MOS stands for a metal-oxide-semiconductor field-effect transistor; SJMOS stands for a super-junction metal-oxide-semiconductor field-effect transistor; IGBT stands for an insulated-gate bipolar transistor; JFET stands for a junction field effect transistor; and HEMT stands for a high electron mobility transistor.

A transistor is defined as follows. A transistor includes a control terminal, a reference terminal, and a high-voltage terminal. The transistor can be turned on by voltage application to the control terminal with reference to the reference terminal.

Turning on the transistor allows current to flow from the high-voltage terminal through the reference terminal, or from the reference terminal through the high-voltage terminal. When an N-type transistor is off, the high-voltage terminal receives voltage with reference to the reference terminal, so that current conduction can be limited. In contrast to this, a P-type transistor receives negative voltage to suppress negative current conduction.

The transistor is an N-type transistor unless otherwise specified.

Transistors include, but not limited to, a MOS, an SJMOS, an IGBT, a GaN-HEMT, and a SiC-JFET having the foregoing definitions of ON and OFF.

In the Specification, a switching circuit SC1 will be also simply referred to as SC1 as an example of the description of a sign in the drawings.

### Overview of First Embodiment

In such a switching circuit provided with two series transistors as disclosed in Japanese Unexamined Patent Application Publication No. 2016-220468, the turn-on operation of its high-withstand-voltage transistor may be unstable in some cases. This unstable turn-on is caused by increase in inductance due to increase in the number of paths resulting from using a plurality of elements. This embodiment discloses a basic configuration for improving the unstable turn-on, and a condition of inductance that can improve a stabilization effect exerted by the basic configuration.

This embodiment discloses the switching circuit SC1 for improving the unstable turn-on, and a boost circuit UC1 with a switching unit of a typical boost circuit replaced with SC1, and with a rectification unit of the typical boost circuit replaced with a rectification circuit UC1.

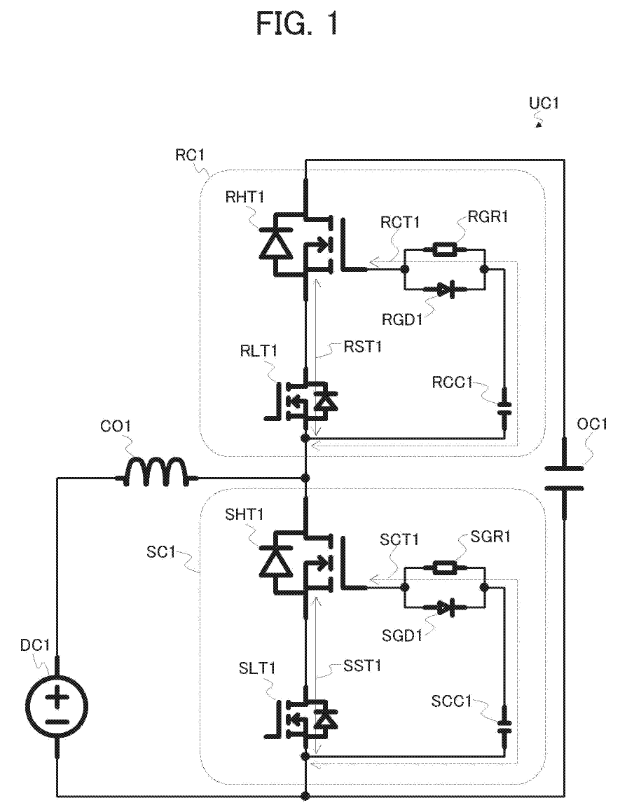

UC1 illustrated in FIG. 1 supplies 400 V to an output capacitor OC1 using 200 V of an input power supply DC1. UC1 includes a coil CO1 of 1 mH.

OC1 has a negative electrode that is the same node as the negative side of DCb; this is defined as a low-voltage side. OC1 has a positive electrode, which is the other end; this is defined as a high-voltage side. The upper side of the drawing sheet is the high-voltage side, and the lower side of the same is the low-voltage side.

### Configuration of Switching Circuit SC1

SC1 has the following basic configuration of its two series transistors.

The configuration of the two series transistors is as follows: a high-withstand-voltage transistor SHT1 is disposed on the high-voltage side, and a low-withstand-voltage transistor SLT1 is disposed on the low-voltage side. A high-voltage terminal of SLT1 is connected to a reference terminal of SHT1. SC1 includes a transistor-series path SST1 from a reference terminal of SLT1 to the reference terminal of SHT1.

A control terminal of SHT1 includes a transistor-control path SCT1 connected to the reference terminal of SLT1. SCT1 includes a gate resistor SGR1, and SGR1 is connected to a gate diode SGD1 in parallel.

SGD1 is structured such that its anode is connected to the control terminal of SHT1, such that its cathode is connected to the reference terminal of SLT1, and such that its inter-terminal capacitance is equal to or less than 20% of the input capacitance of SHT1.

### Transistor’s Terminals in Defining Path’s Inductance

Inductance is pertinent to the length of a wiring line. In considering a location for a connection terminal when attention is focused on the length of a wiring line, it is more accurate, in considering the total length of a wiring line, to regard a connection terminal of a semiconductor wire bond inside a component as a terminal than to regard the distal end of a connection terminal outside the component as a terminal. A terminal that is used for describing a path will be defined as a connection terminal of a semiconductor wire bond.

### Details Of Elements of Switching Circuit SC1

SHT1 is an SJMOS having a drain withstand voltage of 600 V, an ON resistance of 0.1 Ω, and a threshold of 6 V. SLT1 is a MOS having a drain withstand voltage of 30 V, an ON resistance of4 mΩ, and a threshold of 2 V.

The drain withstand voltage of SLT1 is set to be 0.2 times or less of the drain withstand voltage of SHT1, thereby reducing parasitic capacitance caused by the serialization. The ON resistance of SLT1 is set to be a half or less of the ON resistance of SHT1, thereby reducing resistance increase caused by the serialization.

SST1 has an inductance of 7 nH, and SCT1 has an inductance of 30 nH. SHT1 has an input capacitance of 2.3 nF. The input capacitance of SHT1 is defined by a value at the maximum voltage applied to SC1. This maximum voltage excludes instantaneous voltage, such as noise.

The inter-terminal capacitance, which is parasitic capacitance, of SGD1, stands at 70 pF. The inter-terminal capacitance of SGD1 is defined by a value at a reverse voltage of 0.1 V.

SGR1 is connected to a control capacitor SCC1 in series in order to be compatible with SHT1 in normally OFF. SCC1, which performs gate driving on SHT1, is a capacitor connected to an external power supply to be supplied with 15 V.

This voltage 15 V supplied to SCC1 is set to be equal to or greater than the threshold voltage of SHTb, and it is configured such that SHT1 can be turned on when SLT1 is on. When the threshold of SHT1 is equal to or less than 0 V, SCC1 can be omitted.

A gate driving circuit not shown is connected to the control terminal of SLT1, thus controlling ON and OFF of SLT1.

### Configuration of Rectification Circuit RC1

The rectification circuit RC1 has the same configuration as SC1. For instance, RHT1, with the alphabet S at the top of SHT1 replaced with the alphabet R, indicates that RHT1 is composed of the same elements as SHT1. The same holds true for RLT1, RGR1, RGD1, and RCC1. The same holds true for RSTb and RCT1, which are paths.

RC1, which constitutes a rectification circuit of UC1, behaves like a diode that conducts forward current and blocks reverse current. Thus, RLT1 and RHT1 conduct and block the forward current at the same time.

### Principle of Unstable Turn-On

To turn on SHT1, current is fed from SCC1 to SCT1 to start charging the input capacitance of SHT1.

When SHT1 is turned on, turn-on current from CO1 flows through SST1, so that back electromotive voltage opposing the voltage 15 V supplied to SCC1 is generated to inhibit the charging of the input capacitance.

In opposition to the back electromotive voltage of SST1, the current flowing through SCT1 generates back electromotive voltage in SCT1 so that the charging of the input capacitance continues. The back electromotive voltage of SST1 and the back electromotive voltage of SCT1 interfere mutually to bring about voltage oscillation.

Although it is commonly presumed that alternating current resulting from this voltage oscillation can be suppressed by “the resistance value of SGR1” or “the forward voltage and resistance value of SGD1”, a conventional two-series switching circuit cannot sufficiently suppress the alternating current even if these values are changed. This is the starting point of an unstable turn-on problem, which cannot be easily solved.

A detailed analysis has revealed the following fact. It has been found that this alternating current passing through the inter-terminal capacitance of SGD1 makes it difficult to suppress unstable oscillation.

SC1 is configured for suppressing such unstable turn-on.

### Evaluation on Switching Circuit SC1

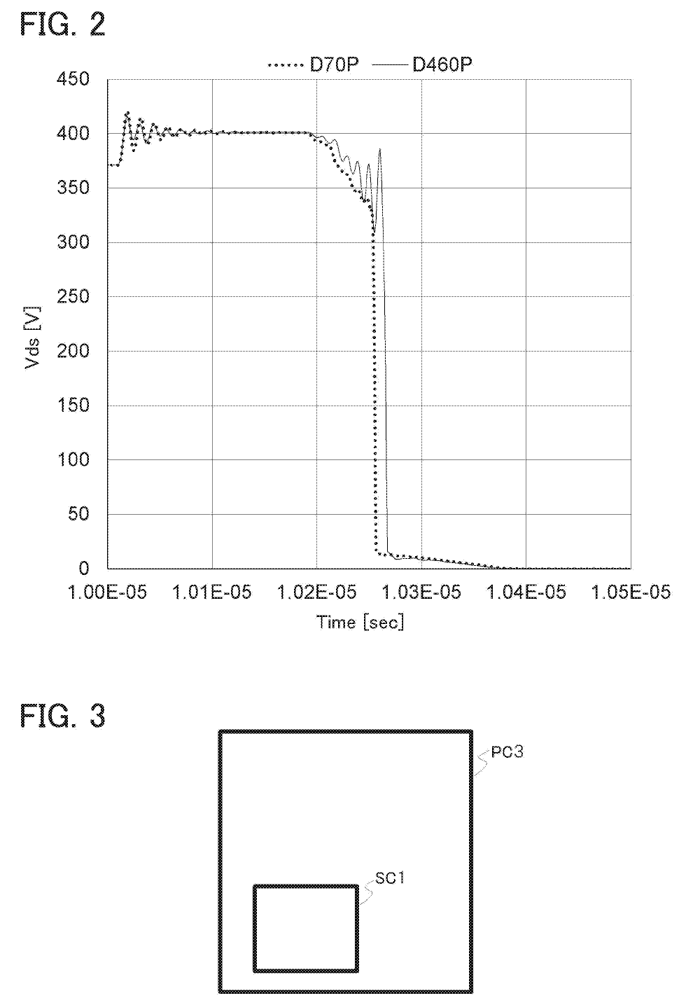

FIG. 2 discloses the voltage waveform of the high-voltage terminal with reference to the reference terminal of SHT1. The lateral axis indicates time, and the drawing shows a turn-on at 1.025E-5 sec. A dotted line D70P indicates data in which the inter-terminal capacitance of SGD1 stands at 70 pF, and a solid line D460P indicates data in which the inter-terminal capacitance of SGD1 stands at 460 pF.

In the range where the voltage drops from 400 V to 350 V, the voltage oscillation of D70P is small, and the voltage oscillation of D70P is large. This is because alternating current resulting from the voltage oscillation flows via the inter-terminal capacitance. Since it is an object to charge the input capacitance of SHT1, and the oscillation current at this time flows through the inter-terminal capacitance, the magnitude of the voltage oscillation can be considered at the ratio of the inter-terminal capacitance of SGD1 with reference to the input capacitance of SHT1.

When the maximum value of the voltage oscillation exceeds the maximum voltage, which is 400 V, applied to SC1, it is necessary to keep problems, such as withstand voltage, in mind in addition to the unstableness caused by the voltage oscillation. The voltage oscillation in which the inter-terminal capacitance 460 pF of SGD1 is 20% of the input capacitance of SHT1 is the upper limit; it is necessary to lower the inter-terminal capacitance to be equal to or less than this value. If possible, the inter-terminal capacitance of SGD1 is desirably set at 10% or less of the input capacitance of SHT1; more desirably, setting the inter-terminal capacitance at 5% or less enables more stable turn-on with less voltage oscillation.

In SC1, the inductances of SST1 and SCT1 are equal to or greater than 5 nH. The effect of SC1 is sufficiently achieved only when the inductances of SST1 and SCT1 are equal to or greater than 5 nH. At an inductance lower than 5 nH, there is a little vibration oscillation to be suppressed, and hence, further improvement of the turn-on stableness is not promising. SC1 is intended for SST1 and SCT1 having their inductances equal to or greater than 5 nH.

The inductance of SCT1 is double or more the inductance of SST1. In some cases, it is necessary to increase either one of the inductances for layout design. The inductance of SCT1 can be increased because it works only during the charging of the input capacitance of SHT1. In view of the balance between the number of elements of SCT1 and the flexibility of the layout design, the inductance of SCT1 is preferably double or more the inductance of SST1.

### Second Embodiment

SC1 and RC1 can be replaced with various switching units or various rectification units.

FIG. 3 illustrates an example where SC1 is incorporated in a power supply circuit PC3. In a power supply circuit that handles alternating current, such as an inverter, it is preferable in some cases to use SC1 and RC1 in a set because the roles of switching and rectification are exchanged in any circuit unit.

PC3 can implement a power supply circuit that enables SC1 to perform stable turn-on.

It should be noted that the foregoing numeral values are merely illustrative. Possible techniques for adjusting the circuit operation include, but not limited to, appropriately interposing a resistor on a wiring line, and appropriately adding a capacitor between two wiring lines to increase electrostatic capacitance.

### Additional Note

The presently contemplated embodiments of the invention disclosed above can be modified in various ways as needed. Such modifications are intended to be incorporated into the appended claims insofar as they are within the scope of the present invention.

What is claimed is:

1. A switching circuit comprising two series transistors,
wherein the switching circuit is structured
such that a high-withstand-voltage transistor is disposed on a high-voltage side, and a low-withstand-voltage transistor is disposed on a low-voltage side, and
such that a high-voltage terminal of the low-withstand-voltage transistor is connected to a reference terminal of the high-withstand-voltage transistor, and
the switching circuit comprises a transistor-series path from a reference terminal of the low-withstand-voltage transistor to the reference terminal of the high-withstand-voltage transistor,
a control terminal of the high-withstand-voltage transistor includes a transistor-control path connected to the reference terminal of the low-withstand-voltage transistor,
wherein the transistor-control path includes a gate resistor,
wherein the gate resistor is connected to a gate diode in parallel, and
wherein the gate diode is structured
such that an anode is connected to the control terminal of the high-withstand-voltage transistor,
such that a cathode is connected to the reference terminal of the low-withstand-voltage transistor, and
such that an inter-terminal capacitance is equal to or less than 20% of an input capacitance of the high-withstand-voltage transistor.

2. The switching circuit according to claim 1, wherein an inductance of the transistor-series path and an inductance of the transistor-control path are equal to or greater than 5 nH.

3. The switching circuit according to claim 2, wherein the inductance of the transistor-control path is double or more the inductance of the transistor-series path.

4. The switching circuit according to claim 1, wherein the gate resistor is connected to a control capacitor in series.

5. A power supply circuit comprising the switching circuit according to claim 1.
